(19) United States
(12) Patent Application Publication
(10) Pub. No.: US 2025/0279789 A1
(43) Pub. Date: Sep. 4, 2025

(54) CONTINUOUS-TIME BANDPASS SIGMA-DELTA MODULATOR AND ELECTRONIC DEVICE

(71) Applicant: Chongqing GigaChip Technology Co., Ltd., Chongqing (CN)

(72) Inventors: Yongshuang LUO, Chongqing (CN); Nan YANG, Chongqing (CN); Xianjie WAN, Chongqing (CN); Youhua WANG, Chongqing (CN); Can ZHU, Chongqing (CN); Dongbing FU, Chongqing (CN)

(73) Assignee: Chongqing GigaChip Technology Co., Ltd., Chongqing (CN)

(21) Appl. No.: 19/186,596

(22) Filed: Apr. 22, 2025

Related U.S. Application Data
(63) Continuation of application No. PCT/CN2022/130870, filed on Nov. 9, 2022.

(30) Foreign Application Priority Data
Oct. 31, 2022 (CN) 202211351788.1

(51) Int. Cl. H03M 3/00

(52) U.S. Cl. CPC H03M 3/408; H03M 3/424; H03M 3/438

(57) ABSTRACT

A continuous-time bandpass Sigma-Delta modulator includes a transconductance operational amplifier, a passive resonator, a sampling quantizer, a current feedback module, and a voltage feedback module. The transconductance operational amplifier receives an input voltage signal and convert it to output a current signal. The passive resonator is connected to an output end of the transconductance operational amplifier as a loop filter and converts the current signal to output an intermediate voltage signal. The sampling quantizer is connected to an output end of the passive resonator and samples and quantizes the intermediate voltage signal to output a thermometer code. The current feedback module and the voltage feedback module both are connected to the sampling quantizer and the passive resonator, and respectively provide a feedback current and a feedback voltage for the passive resonator under control of the thermometer code.

### CROSS REFERENCE TO RELATED APPLICATION

The present disclosure is a continuation application of International Patent Application No. PCT/CN2022/130870, filed on Nov. 9, 2022, and claiming the priority to Chinese Application No. 202211351788.1 filed on Oct. 31, 2022, the contents of all of which are incorporated herein by reference in their entirety for all purposes.

### TECHNICAL FIELD

The present application relates to the technical field of integrated circuits, and in particular to a continuous-time bandpass Sigma-Delta modulator and an electronic device.

### BACKGROUND

The continuous-time Sigma-Delta modulator has the characteristics of low power consumption and high speed and also has its own anti-aliasing characteristics, which greatly reduces the design requirements for the anti-aliasing filter of the previous stage, and effectively reduces the chip area. These characteristics make the continuous-time Sigma-Delta modulator widely used. The bandpass continuous-time Sigma-Delta modulator can directly digitize the intermediate frequency signal while having the aforementioned characteristics, greatly simplifying the complexity of the receiver system. The loop filter in the bandpass continuous-time Sigma-Delta modulator usually includes a resonator composed of an active RC integrator or a resonator composed of an inductor and a capacitor. Since the inductor-capacitor resonator is a passive device and is ideally only an energy storage device, there is no power consumption. In addition, the inductor-capacitor resonator can achieve a higher quality factor and provide earlier gain, which makes its noise performance better than the resonator composed of an active RC integrator.

### SUMMARY

In one aspect of the present application, a continuous-time bandpass Sigma-Delta modulator includes: a transconductance operational amplifier receiving an input voltage signal and converting the input voltage signal to obtain and output a current signal; a passive resonator connected to an output end of the transconductance operational amplifier as a loop filter and converting the current signal to obtain and output an intermediate voltage signal; a sampling quantizer connected to an output end of the passive resonator and sampling and quantizing the intermediate voltage signal to obtain and output a thermometer code; a current feedback module having an input end connected to an output end of the sampling quantizer and an output end connected to the passive resonator and providing a feedback current for the passive resonator under the control of the thermometer code; and a voltage feedback module having an input end connected to the output end of the sampling quantizer and an output end connected to the passive resonator and providing a feedback voltage for the passive resonator under the control of the thermometer code.

In one or more embodiments, the passive resonator includes a capacitor and an inductor; one end of the capacitor is connected to the output end of the transconductance operational amplifier, the other end of the capacitor is grounded; one end of the inductor is connected to the output end of the transconductance operational amplifier, the other end of the inductor is connected to the output end of the sampling quantizer through the voltage feedback module connected in series; and the end of the inductor connected to the output end of the transconductance operational amplifier outputs the intermediate voltage signal.

In one or more embodiments, the thermometer code includes a 4-bit thermometer code; the current feedback module includes a first current source, a second current source, a third current source, a fourth current source, a fifth current source, a first switch, a second switch, a third switch, and a fourth switch; an operation voltage is grounded through the first current source, the first switch, and the second current source connected in series in sequence; the operation voltage is also grounded through the first current source, the second switch, and the third current source connected in series in sequence; the operation voltage is also grounded through the first current source, the third switch, and the fourth current source connected in series in sequence; the operation voltage is also grounded through the first current source, the fourth switch, and the fifth current source connected in series in sequence; a control end of the first switch is connected to a first bit of the 4-bit thermometer code; a control end of the second switch is connected to a second bit of the 4-bit thermometer code; a control end of the third switch is connected to a third bit of the 4-bit thermometer code; a control end of the fourth switch is connected to a fourth bit of the 4-bit thermometer code; a common end of the first switch, the second switch, the third switch, and the fourth switch outputs the feedback current; and the feedback current is connected to the output end of the transconductance operational amplifier.

In one or more embodiments, the voltage feedback module includes an output voltage adjusting unit, a voltage dividing unit, and a selection output unit; the output voltage adjusting unit outputs an adjustable initial voltage; an input end of the voltage dividing unit is connected to an output end of the output voltage adjusting unit; the voltage dividing unit performs voltage dividing processing in combination with ground, the operation voltage, and the initial voltage to obtain and output a plurality of initial feedback voltages of different values; input ends of the selection output unit are connected to the plurality of initial feedback voltages in a one-to-one correspondence; a control end of the selection output unit is connected to the thermometer code; under the control of the thermometer code, the selection output unit selects one of the plurality of initial feedback voltages as the feedback voltage and outputs the feedback voltage; and an output end of the selection output unit is connected to an end of the inductor away from the transconductance operational amplifier.

In one or more embodiments, the output voltage adjusting unit includes N reference current sources, N digitally controlled switches, a first resistor, a first operational amplifier, and an NMOS transistor; the N reference current sources and the N digitally controlled switches form N parallel current branches; each of the current branches includes one reference current source and one digitally controlled switch connected in series in sequence; an end of each reference current source away from the digitally controlled switch is connected to the operation voltage; control ends of the N digitally controlled switches are connected to N bits of an N-bit digital code in a one-to-one correspondence; ends of the N digitally controlled switches away from the reference current sources are connected to one end of the first resistor, the other end of the first resistor is grounded; a non-inverting input end of the first operational amplifier is connected to a common end of the N digitally controlled switches, an inverting input end of the first operational amplifier is connected to a source of the NMOS transistor, an output end of the first operational amplifier is connected to a gate of the NMOS transistor, and the source of the NMOS transistor outputs the initial voltage, wherein N is an integer greater than or equal to 2.

In one or more embodiments, the voltage dividing unit includes a second resistor and four third resistors; the operation voltage is connected to a drain of the NMOS transistor through a first third resistor, a second third resistor, a third third resistor, and a fourth third resistor connected in series in sequence; the source of the NMOS transistor is grounded through the second resistor connected in series; an end of the first third resistor close to the operation voltage outputs an initial feedback voltage, the first third resistor and the second third resistor have a common end that outputs an initial feedback voltage, the second third resistor and the third third resistor have a common end that outputs an initial feedback voltage, the third third resistor and the fourth third resistor have a common end that outputs an initial feedback voltage, and an end of the fourth third resistor close to the NMOS transistor outputs an initial feedback voltage.

In one or more embodiments, the selection output unit includes a data selector and a second operational amplifier; five input ends of the data selector are connected to five initial feedback voltages in a one-to-one correspondence, a control end of the data selector is connected to the thermometer code, an output end of the data selector is connected to a non-inverting input end of the second operational amplifier, an inverting input end of the second operational amplifier is connected to an output end of the second operational amplifier, and the output end of the second operational amplifier outputs the feedback voltage.

In one or more embodiments, the voltage feedback module further includes an output common-mode adjustment unit, an output end of the output common-mode adjustment unit is connected to the voltage dividing unit, and the output common-mode adjustment unit stabilizes and clamps a common-mode value of the feedback voltage.

In one or more embodiments, the output common-mode adjustment unit includes a third operational amplifier and a P MOS transistor, a source of the PMOS transistor is connected to the operation voltage, a gate of the PMOS transistor is connected to an output end of the third operational amplifier, an inverting input end of the third operational amplifier is connected to a reference voltage, a non-inverting input end of the third operational amplifier is connected to the common end of the second third resistor and the third third resistor, and a drain of the P MOS transistor is connected to an end of the first third resistor away from the second third resistor.

In another aspect of the present application, an electronic device includes a continuous-time bandpass Sigma-Delta modulator as described in any one of the above items.

### BRIEF DESCRIPTION OF DRAWINGS

FIG. 1 shows a block diagram of a structure of a continuous-time bandpass Sigma-Delta modulator in the present application.

FIG. 2 shows a circuit structure diagram of a current feedback module 4 in FIG. 1.

FIG. 3 shows a circuit structure diagram of a voltage feedback module 5 in FIG. 1.

FIG. 4 shows a block diagram of a structure of a continuous-time bandpass Sigma-Delta modulator of a CRFB structure.

### DESCRIPTION OF EMBODIMENTS

The following describes the embodiments of the present application through specific examples, and those skilled in the art can easily understand other advantages and effects of the present application from the contents disclosed in this specification. The present application can also be implemented or applied through other different specific embodiments, and the details in this specification can also be modified or changed in various ways based on different viewpoints and applications without departing from the spirit of the present application.

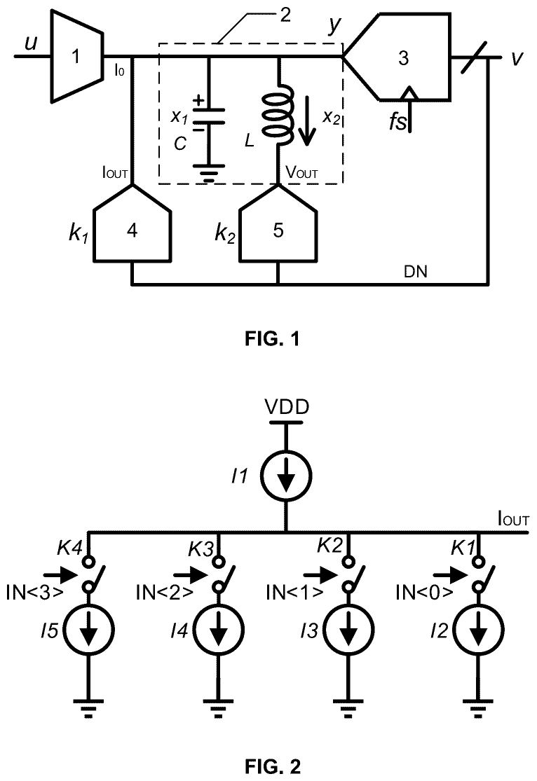

Please refer to FIGS. 1 to 4. It should be noted that the diagrams provided in these embodiments only illustrate the basic concept of the present application in a schematic manner, so the diagrams only show the components related to the present application rather than being drawn according to the number, shape, and size of the components during actual implementation. The type, quantity, and scale of each component during actual implementation can be changed at will, and the component layout type may also be more complicated. The structure, proportion, size, etc. shown in the drawings attached to this specification are only used to match the content disclosed in the specification for people familiar with this technology to understand and read and are not used to limit the limiting conditions that the present application can be implemented, so they have no technical substantive significance. Any structural modification, change in proportional relationship, or adjustment of size should still fall within the scope of the technical content disclosed by the present application without affecting the effect that the present application can produce and the purpose that can be achieved.

The existing continuous-time bandpass Sigma-Delta modulator technology based on the inductor-capacitor resonator has only one current signal as feedback of the modulator output for a second-order inductor-capacitor resonator. The lack of a feedback degree of freedom makes it impossible to realize arbitrary bandpass Sigma-Delta modulator noise transfer function. This limits the selection of loop parameters in the design of the continuous-time bandpass Sigma-Delta modulator based on the inductor-capacitor resonator, which directly affects the performance of the entire modulator.

Therefore, there is an urgent need for a technical solution based on more feedback degrees of freedom that can realize any bandpass Sigma-Delta modulator noise transfer function.

The present application provides a continuous-time bandpass Sigma-Delta modulator based on an inductor-capacitor resonator, which adds voltage feedback on the basis of current feedback to make up for the missing degree of freedom and solve the limitation of the missing degree of freedom on the system performance of the continuous-time bandpass Sigma-Delta modulator based on the inductor-capacitor resonator.

As described above, the inventors have found that in the existing continuous-time bandpass Sigma-Delta modulator technology based on the inductor-capacitor resonator, for a second-order inductor-capacitor resonator, the feedback of the modulator output only includes one current signal based on the current feedback module. The feedback degree of freedom is small, resulting in the inability of the conventional technique to realize arbitrary bandpass Sigma-Delta modulator noise transfer function, which in turn limits the selection of loop parameters in the design of the continuous-time bandpass Sigma-Delta modulator based on the inductor-capacitor resonator, directly affecting the performance of the entire modulator.

Based on this, as shown in FIG. 1, the present application proposes a continuous-time bandpass Sigma-Delta modulator, which includes: a transconductance operational amplifier 1 receiving an input voltage signal u and converting the input voltage signal u to obtain and output a current signal I₀; a passive resonator 2, as a loop filter, connected to the output end of the transconductance operational amplifier 1 and converting the current signal I₀ to obtain and output an intermediate voltage signal x1; a sampling quantizer 3 connected to an output end of the passive resonator 2, sampling and quantizing the intermediate voltage signal x1 to obtain and output a thermometer code DN; a current feedback module 4 having an input end connected to an output end of the sampling quantizer 3 and an output end connected to the passive resonator 2, and providing a feedback current I_{OUT} for the passive resonator 2 under the control of the thermometer code DN; and a voltage feedback module 5 having an input end connected to the output end of the sampling quantizer 3 and an output end connected to the passive resonator 2, and providing a feedback voltage V_{OUT} for the passive resonator 2 under the control of the thermometer code DN.

In one or more embodiments, the transconductance operational amplifier 1 may adopt a conventional transconductance operational amplifying structure, and its corresponding transconductance is gₘ. It converts the input voltage signal u to obtain and output the current signal I₀, and I₀=gₘu.

In one or more embodiments, as shown in FIG. 1, the passive resonator 2 is an inductor-capacitor type resonator, which includes a capacitor C and an inductor L. One end of the capacitor C is connected to the output end of the transconductance operational amplifier 1, and the other end of the capacitor C is grounded. One end of the inductor L is connected to the output end of the transconductance operational amplifier 1, and the other end of the inductor L is connected to the output end of the sampling quantizer 3 through a series-connected voltage feedback module 5. One end of the inductor L connected to the output end of the transconductance operational amplifier 1 outputs the intermediate voltage signal x1, and the intermediate voltage signal x1 is the voltage on the capacitor C.

In one or more embodiments, in an optional embodiment of the present application, as shown in FIGS. 1 to 2, the sampling quantizer 3 can be a 5-level parallel comparison type analog-to-digital converter, which samples, at a sampling frequency fs, and quantizes the intermediate voltage signal x1 on the passive resonator 2, and obtains a 4-bit thermometer code DN namely, IN<0>, IN<1>, IN<2>, and IN<3> shown in FIG. 2 by analog-to-digital conversion, and the corresponding digital voltage is recorded as v. It can be understood that the sampling quantizer 3 can also be an analog-to-digital converter with other structures and other numbers of bits, which is not limited here.

In one or more embodiments, in an optional embodiment of the present application, as shown in FIG. 2, the current feedback module 4 includes a first current source I1, a second current source I2, a third current source I3, a fourth current source I4, a fifth current source I5, a first switch K1, a second switch K2, a third switch K3, and a fourth switch K4. The operation voltage VDD is connected to the ground via the first current source I1, the first switch K1, and the second current source I2 which are connected in series in sequence. The operation voltage VDD is also connected to the ground via the first current source I1, the second switch K2, and the third current source I3 which are connected in series in sequence. The operation voltage VDD is also connected to the ground via the first current source I1, the third switch K3, and the fourth current source I4 which are connected in series in sequence. The operation voltage VDD is also connected to the ground via the first current source I1, the fourth switch K4, and the fifth current source I5 which are connected in series in sequence. The control end of the first switch K1 is connected to the first bit IN<0> of the 4-bit thermometer code DN, the control end of the second switch K2 is connected to the second bit IN<1> of the 4-bit thermometer code DN, the control end of the third switch K3 is connected to the third bit IN<2> of the 4-bit thermometer code DN, and the control end of the fourth switch K4 is connected to the fourth bit IN<3> of the 4-bit thermometer code DN. A common end of the first switch K1, the second switch K2, the third switch K3, and the fourth switch K4 outputs the feedback current I_{OUT}, and the feedback current I_{OUT} is connected to the output end of the transconductance operational amplifier 1.

In one or more embodiments, the output current of the first current source I1 is I₁, the output currents of the second current source I2, the third current source I3, the fourth current source I4, and the fifth current source I5 are equal and denoted as I₂, and I₁=2I₂. The output feedback current I_{OUT} can be adjusted by gate-controlling of IN<0>, IN<1>, IN<2>, and IN<3>. In addition, the output currents of the first current source I1, the second current source I2, the third current source I3, the fourth current source I4, and the fifth current source I5 can be set arbitrarily, without limitation thereto.

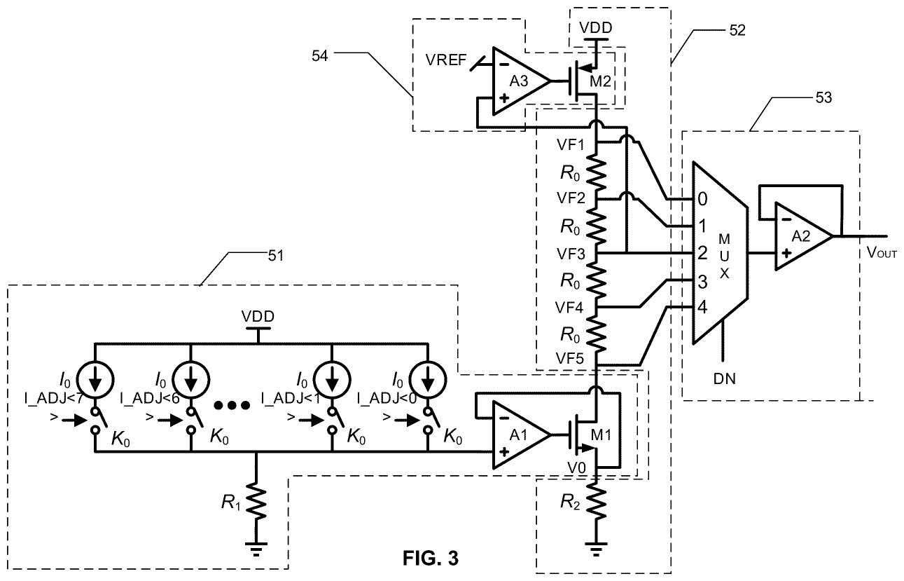

In one or more embodiments, in an optional embodiment of the present application, as shown in FIG. 3, the voltage feedback module 5 includes an output voltage adjusting unit 51, a voltage dividing unit 52, and a selection output unit 53. The output voltage adjusting unit 51 outputs an adjustable initial voltage V0. The input end of the voltage dividing unit 52 is connected to the output end of the output voltage adjusting unit 51. The voltage dividing unit 52 performs voltage dividing processing on the ground, the operation voltage VDD, and the initial voltage V0 to obtain and output a plurality of initial feedback voltages of different values, such as VF1 to VF5. A plurality of input ends of the selection output unit 53 is connected to the plurality of initial feedback voltages in a one-to-one correspondence. The control end of the selection output unit 53 is connected to the thermometer code DN. Under the control of the thermometer code DN, the selection output unit 53 selects one of the plurality of initial feedback voltages as the feedback voltage V_{OUT} and outputs it. The output end of the selection output unit 53 is connected to an end of the inductor L away from the transconductance operational amplifier 1.

In one or more embodiments, as shown in FIG. 3, the output voltage adjusting unit 51 includes N reference current sources I₀, N digitally controlled switches K₀, a first resistor R₁, a first operational amplifier A1, and an NMOS transistor M1. The N reference current sources I₀ and the N digitally controlled switches K₀ form N parallel current branches. Each current branch includes one reference current source I₀ and one digitally controlled switch K₀ connected in series in sequence. An end of each reference current source I₀ away from the digitally controlled switch K₀ is connected to the operation voltage VDD. The control ends of the N digitally controlled switches K₀ are connected to the N bits of the N-bit digital code in a one-to-one correspondence, such as the 8-bit digital code shown in I_ADJ<0:7> in the figure. Ends of the N digitally controlled switches K₀ away from the reference current sources I₀ are connected to one end of the first resistor R₁. The other end of the first resistor R₁ is grounded. The non-inverting input end of the first operational amplifier A1 is connected to the common end of the N digitally controlled switches K₀, the inverting input end of the first operational amplifier A1 is connected to the source of the NMOS transistor M1, the output end of the first operational amplifier A1 is connected to the gate of the NMOS transistor M1, and the source of the NMOS transistor M1 outputs an initial voltage V0, where N is an integer greater than or equal to 2.

In one or more embodiments, the digital code used for the on-off control of the digitally controlled switches K₀ is 8-bit I_ADJ<0:7>, corresponding to 8 current branches, and the value of N is 8. It should be noted that the digital code used for the on-off control of the digitally controlled switches K₀ is not limited to the 8-bit I_ADJ<0:7> shown in FIG. 1, and can also be a digital code of any other number of bits, which is specifically determined by the value of N and is not limited here.

In one or more embodiments, as shown in FIG. 3, the on-off of the N current branches in the output voltage adjusting unit 51 is controlled by adjusting and controlling the N-bit digital code to adjust the current flowing through the first resistor R₁, thereby adjusting the voltage at the non-inverting input end of the first operational amplifier A1. The first operational amplifier A1 combines with the NMOS transistor M1 to follow and output the voltage at the non-inverting input end of the first operational amplifier A1, and an initial voltage V0 is obtained at the source of the NMOS transistor M1. The initial voltage V0 can be adjusted and controlled by the N-bit digital code, and the least significant bit (LSB) or resolution of the voltage feedback module 5 can be reconfigured. Assuming that the current flowing through the first resistor R₁ is n×I₀, where n is an integer from 0 to N, then an LSB of the voltage feedback module 5 can be expressed as:

$${LSB}_{VDAC} = \frac{{nI}_{0} {R}_{0} {R}_{1}}{{R}_{2}} . \qquad ( 1 )$$

In one or more embodiments, as shown in FIG. 3, the voltage dividing unit 52 includes a second resistor R₂ and four third resistors R₀. The operation voltage VDD is sequentially connected in series to the first third resistor R₀, the second third resistor R₀, the third third resistor R₀, and the fourth third resistor R₀, then connected to the drain of the NMOS transistor M1 via. The source of the NMOS transistor M1 is connected in series to the second resistor R₂, then grounded. An end of the first third resistor R₀ close to the operation voltage VDD outputs an initial feedback voltage VF1, the common end of the first third resistor R₀ and the second third resistor R₀ outputs an initial feedback voltage VF2, the common end of the second third resistor R₀ and the third third resistor R₀ outputs an initial feedback voltage VF3, the common end of the third third resistor R₀ and the fourth third resistor R₀ outputs an initial feedback voltage VF4, and an end of the fourth third resistor R₀ close to the NMOS transistor M1 outputs an initial feedback voltage VF5.

In one or more embodiments, as shown in FIG. 3, the voltage dividing unit 52 performs voltage division processing on the ground, the operation voltage VDD, and the initial voltage V0 to obtain and output five initial feedback voltages VF1 to VF5 of different values. In one or more embodiments, the number and resistance of the voltage dividing resistors in the voltage dividing unit 52 can be selected according to actual needs and are not limited here. The five initial feedback voltages VF1 to VF5 in FIG. 3 just correspond to the 4-bit thermometer code DN.

In one or more embodiments, as shown in FIG. 3, the selection output unit 53 includes a data selector MUX and a second operational amplifier A2. Five input ends of the data selector MUX are connected to the five initial feedback voltages VF1 to VF5 in one-to-one correspondence. The control end of the data selector MUX is connected to the thermometer code DN, the output end of the data selector MUX is connected to the non-inverting input end of the second operational amplifier A2, the inverting input end of the second operational amplifier A2 is connected to the output end of the second operational amplifier A2, and the output end of the second operational amplifier A2 outputs the feedback voltage V_{OUT}.

In one or more embodiments, as shown in FIG. 3, the data selector MUX selects and outputs each input initial feedback voltage, and its control method is that if there are i high levels in the input thermometer code DN, then the data selector MUX outputs the i-th initial feedback voltage, and this initial feedback voltage is subjected to following and outputting process by the second operational amplifier A2 to obtain the feedback voltage V_{OUT}.

In one or more embodiments, as shown in FIG. 3, the voltage feedback module 5 further includes an output common mode adjustment unit 54, the output end of the output common mode adjustment unit 54 is connected to the voltage dividing unit 52, and the output common mode adjustment unit 54 stably clamps the common mode value of the feedback voltage V_{OUT}.

In one or more embodiments, as shown in FIG. 3, the output common-mode adjustment unit 54 includes a third operational amplifier A3 and a PMOS transistor M2, the source of the PMOS transistor M2 is connected to the operation voltage VDD, the gate of the P MOS transistor M2 is connected to the output end of the third operational amplifier A3, the inverting input end of the third operational amplifier A3 is connected to the reference voltage VREF, the non-inverting input end of the third operational amplifier A3 is connected to the common end of the second third resistor R₀ and the third third resistor R₀, and the drain of the PMOS transistor M2 is connected to an end of the first third resistor R₀ away from the second third resistor R₀.

In one or more embodiments, as shown in FIG. 3, through the virtual short function of the third operational amplifier A3, the voltage value of the initial feedback voltage VF3 is stabilized at the reference voltage VREF, and the initial feedback voltage VF3 is the median voltage of the entire voltage dividing unit 52, thereby stably clamping the common mode value of the feedback voltage V_{OUT} at VREF.

In one or more embodiments, the continuous-time bandpass Sigma-Delta modulator shown in FIG. 1 is of a cascade resonator feedback (CRFB) structure, and its working principle is as follows.

The loop filter in a continuous-time bandpass Sigma-Delta modulator is implemented using an inductor-capacitor resonator. Unlike the active RC resonator, the two integrator state variables of the resonator are a voltage signal and a current signal, which are the voltage x₁ on the capacitor C and the current x₂ on the inductor L. Therefore, the state equation of the loop filter is:

$$\{ \begin{matrix}C \frac{{dx}_{1}}{dt} = {g}_{m} u - {k}_{1} v - {x}_{2} \\ L \frac{{dx}_{2}}{dt} = {x}_{1} - {k}_{2} v \\ y = {x}_{2}\end{matrix} , \qquad ( 2 )$$

where K1 is the current amplification factor of the current feedback module 4, K2 is the voltage amplification factor of the voltage feedback module 5, y is the input of the sampling quantizer 3, and v is the output of the sampling quantizer 3.

By Laplace transforming the above equations, we can get:

$$\{ \begin{matrix}{sX}_{1} = \frac{{g}_{m}}{C} U - \frac{{k}_{1}}{C} V - \frac{1}{C} {X}_{2} \\ {sX}_{2} = \frac{1}{L} {X}_{1} - \frac{{k}_{2}}{L} V \\ Y = {X}_{2}\end{matrix} . \qquad ( 3 )$$

Then, the ABCD matrix of the modulator is:

$${ABCD}_{3 \times 4} = [ \begin{matrix}0 & - \frac{1}{C} & \frac{{g}_{m}}{C} & - \frac{{k}_{1}}{C} \\ \frac{1}{L} & 0 & 0 & - \frac{{k}_{2}}{C} \\ 0 & 1 & 0 & 0\end{matrix} ] . \qquad ( 4 )$$

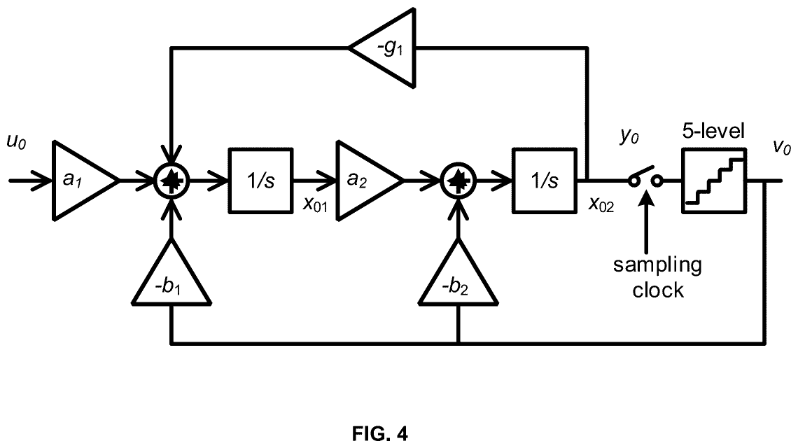

In addition, the general system block diagram of the continuous-time bandpass Sigma-Delta modulator of the cascade resonator feedback structure is shown in FIG. 4, and its detailed structural parameters can be found in the conventional technique, which will not be repeated here, and its sampling clock frequency is generally normalized 1 Hz. The Laplace transform of the modulator state equation of the cascade resonator feedback structure is as follows:

$$\{ \begin{matrix}{sX}_{01} = {a}_{1} {U}_{0} - {b}_{1} {V}_{0} - {g}_{1} {X}_{2} \\ {sX}_{02} = {a}_{2} {X}_{01} - {b}_{2} {V}_{0} \\ {Y}_{0} = {X}_{02}\end{matrix} . \qquad ( 5 )$$

Then, the ABCD matrix of the modulator is:

$${ABCD}_{3 \times 4} = [ \begin{matrix}0 & - {g}_{1} & {a}_{1} & - {b}_{1} \\ {a}_{2} & 0 & 0 & - {b}_{2} \\ 0 & 1 & 0 & 0\end{matrix} ] . \qquad ( 6 )$$

With a comparison between the ABCD matrix of the continuous-time bandpass Sigma-Delta modulator of the present application represented by equation (4) and the ABCD matrix of the continuous-time bandpass Sigma-Delta modulator of the general cascade resonator feedback structure represented by equation (6), it can be seen that, with appropriate configuration of the loop filter parameters (such as the inductance value of the inductor L, the capacitance value of the inductor C, the LSB of the current feedback module 4, the LSB of the voltage feedback module 5, and the transconductance gₘ of the transconductance operational amplifier, etc.), equation (4) and equation (6) can be completely equal.

That is to say, with the appropriate configuration of the loop filter parameters, the continuous-time bandpass sigma-delta modulator based on the inductor-capacitor resonator of the present application can realize any bandpass sigma-delta modulator noise transfer function.

Therefore, in the present application, a continuous-time bandpass Sigma-Delta modulator is designed by combining a transconductance operational amplifier, a passive resonator, a sampling quantizer, a current feedback module, and a voltage feedback module. Voltage feedback is added based on conventional current feedback, and current feedback and voltage feedback can be realized simultaneously, thereby increasing the feedback degree of freedom, so that the entire modulator can realize any bandpass Sigma-Delta modulator noise transfer function. This effectively solves the limitation on the system performance of the continuous-time bandpass Sigma-Delta modulator based on the inductor-capacitor resonator due to the lack of feedback degree of freedom and improves the performance of the modulator.

The present application is also applicable to quantizers of other different levels or continuous-time bandpass Sigma-Delta modulators of other multiple inductor-capacitor resonators.

In addition, the present application also provides an electronic device, which includes the above-mentioned continuous-time bandpass Sigma-Delta modulator. Based on the design of current feedback plus voltage feedback in the above-mentioned continuous-time bandpass Sigma-Delta modulator, the feedback degree of freedom is increased, so that the entire modulator can realize any bandpass Sigma-Delta modulator noise transfer function, which effectively solves the limitation on the system performance of the continuous-time bandpass Sigma-Delta modulator based on the inductor-capacitor resonator due to the lack of feedback degree of freedom, improves the performance of the modulator, and improves the performance of the entire electronic device.

In summary, in the continuous-time bandpass Sigma-Delta modulator and electronic device provided by the present application, a continuous-time bandpass Sigma-Delta modulator is designed in combination with a transconductance operational amplifier, a passive resonator, a sampling quantizer, a current feedback module, and a voltage feedback module. Voltage feedback is added based on conventional current feedback, and current feedback and voltage feedback can be realized simultaneously, thereby increasing the feedback degree of freedom, so that the entire modulator can realize any bandpass Sigma-Delta modulator noise transfer function. This effectively solves the limitation on the system performance of the continuous-time bandpass Sigma-Delta modulator based on the inductor-capacitor resonator due to the lack of feedback degree of freedom and improves the performance of the modulator.

As described above, the continuous-time bandpass Sigma-Delta modulator and electronic device of the present application have at least the following beneficial effects.

A continuous-time bandpass Sigma-Delta modulator is designed by combining a transconductance operational amplifier, a passive resonator, a sampling quantizer, a current feedback module, and a voltage feedback module. Voltage feedback is added based on conventional current feedback, which can realize current feedback and voltage feedback at the same time, and increase the feedback degree of freedom. The entire modulator can realize any bandpass Sigma-Delta modulator noise transfer function, which effectively solves the limitation on the performance of the continuous-time bandpass Sigma-Delta modulator system based on the inductor-capacitor resonator due to the lack of feedback degree of freedom, and improves the performance of the modulator.

The above embodiments are merely illustrative of the principles and effects of the present application, and are not intended to limit the present application. Anyone familiar with the art may modify or alter the above embodiments without departing from the spirit and scope of the present application. Therefore, all equivalent modifications or alterations made by a person of ordinary skill in the art without departing from the spirit and technical concept disclosed by the present application shall still be covered by the claims of the present application.

What is claimed is:

1. A continuous-time bandpass Sigma-Delta modulator, comprising:
a transconductance operational amplifier configured to receive an input voltage signal and convert the input voltage signal to obtain and output a current signal;
a passive resonator connected to an output end of the transconductance operational amplifier as a loop filter and configured to convert the current signal to obtain and output an intermediate voltage signal;
a sampling quantizer connected to an output end of the passive resonator and configured to sample and quantize the intermediate voltage signal to obtain and output a thermometer code;
a current feedback module, an input end of the current feedback module connected to an output end of the sampling quantizer, an output end of the current feedback module connected to the passive resonator, and the current feedback module configured to provide a feedback current for the passive resonator under control of the thermometer code; and
a voltage feedback module, an input end of the voltage feedback module connected to the output end of the sampling quantizer, an output end of the voltage feedback module connected to the passive resonator, and the voltage feedback module configured to provide a feedback voltage for the passive resonator under the control of the thermometer code.

2. The continuous-time bandpass Sigma-Delta modulator according to claim 1, wherein the passive resonator includes a capacitor and an inductor; a first end of the capacitor is connected to the output end of the transconductance operational amplifier, a second end of the capacitor is grounded; a first end of the inductor is connected to the output end of the transconductance operational amplifier, a second end of the inductor is connected to the output end of the sampling quantizer through the voltage feedback module connected in series; and the first end of the inductor connected to the output end of the transconductance operational amplifier outputs the intermediate voltage signal.

3. The continuous-time bandpass Sigma-Delta modulator according to claim 2, wherein the thermometer code includes a 4-bit thermometer code; the current feedback module includes a first current source, a second current source, a third current source, a fourth current source, a fifth current source, a first switch, a second switch, a third switch, and a fourth switch; an operation voltage is grounded through the first current source, the first switch, and the second current source connected in series in sequence; the operation voltage is also grounded through the first current source, the second switch, and the third current source connected in series in sequence; the operation voltage is also grounded through the first current source, the third switch, and the fourth current source connected in series in sequence; the operation voltage is also grounded through the first current source, the fourth switch, and the fifth current source connected in series in sequence; a control end of the first switch is connected to a first bit of the 4-bit thermometer code; a control end of the second switch is connected to a second bit of the 4-bit thermometer code; a control end of the third switch is connected to a third bit of the 4-bit thermometer code; a control end of the fourth switch is connected to a fourth bit of the 4-bit thermometer code; a common end of the first switch, the second switch, the third switch, and the fourth switch outputs the feedback current; and the feedback current is connected to the output end of the transconductance operational amplifier.

4. The continuous-time bandpass Sigma-Delta modulator according to claim 3, wherein the voltage feedback module includes an output voltage adjusting unit, a voltage dividing unit, and a selection output unit; the output voltage adjusting unit outputs an adjustable initial voltage; an input end of the voltage dividing unit is connected to an output end of the output voltage adjusting unit; the voltage dividing unit performs voltage dividing processing in combination with ground, the operation voltage, and the initial voltage to obtain and output a plurality of initial feedback voltages of different values; input ends of the selection output unit are connected to the plurality of initial feedback voltages in a one-to-one correspondence; a control end of the selection output unit is connected to the thermometer code; under the control of the thermometer code, the selection output unit selects one of the plurality of initial feedback voltages as the feedback voltage and outputs the feedback voltage; and an output end of the selection output unit is connected to the second end of the inductor away from the transconductance operational amplifier.

5. The continuous-time bandpass Sigma-Delta modulator according to claim 4, wherein the output voltage adjusting unit includes N reference current sources, N digitally controlled switches, a first resistor, a first operational amplifier, and an NMOS transistor; the N reference current sources and the N digitally controlled switches form N parallel current branches; each of the current branches includes one reference current source and one digitally controlled switch connected in series in sequence; an end of each reference current source away from the digitally controlled switch is connected to the operation voltage; control ends of the N digitally controlled switches are connected to N bits of an N-bit digital code in a one-to-one correspondence; ends of the N digitally controlled switches away from the reference current sources are connected to a first end of the first resistor, a second end of the first resistor is grounded; a non-inverting input end of the first operational amplifier is connected to a common end of the N digitally controlled switches, an inverting input end of the first operational amplifier is connected to a source of the NMOS transistor, an output end of the first operational amplifier is connected to a gate of the NMOS transistor, and the source of the NMOS transistor outputs the initial voltage, wherein N is an integer greater than or equal to 2.

6. The continuous-time bandpass Sigma-Delta modulator according to claim 5, wherein the voltage dividing unit includes a second resistor and four third resistors; the operation voltage is connected to a drain of the NMOS transistor through a first third resistor, a second third resistor, a third third resistor, and a fourth third resistor connected in series in sequence; the source of the NMOS transistor is grounded through the second resistor connected in series; an end of the first third resistor close to the operation voltage outputs a first initial feedback voltage of the initial feedback voltages, a common end of the first third resistor and the second third resistor outputs a second initial feedback voltage of the initial feedback voltages, a common end of the second third resistor and the third third resistor outputs a third initial feedback voltage of the initial feedback voltages, a common end of the third third resistor and the fourth third resistor outputs a fourth initial feedback voltage of the initial feedback voltages, and an end of the fourth third resistor close to the NMOS transistor outputs a fifth initial feedback voltage the initial feedback voltages.

7. The continuous-time bandpass Sigma-Delta modulator according to claim 6, wherein the selection output unit includes a data selector and a second operational amplifier; five input ends of the data selector are connected to five initial feedback voltages in a one-to-one correspondence, a control end of the data selector is connected to the thermometer code, an output end of the data selector is connected to a non-inverting input end of the second operational amplifier, an inverting input end of the second operational amplifier is connected to an output end of the second operational amplifier, and the output end of the second operational amplifier outputs the feedback voltage.

8. The continuous-time bandpass Sigma-Delta modulator according to claim 6, wherein the voltage feedback module further includes an output common-mode adjustment unit, an output end of the output common-mode adjustment unit is connected to the voltage dividing unit, and the output common-mode adjustment unit is configured to stabilize and clamp a common-mode value of the feedback voltage.

9. The continuous-time bandpass Sigma-Delta modulator according to claim 8, wherein the output common-mode adjustment unit includes a third operational amplifier and a PMOS transistor, a source of the PMOS transistor is connected to the operation voltage, a gate of the PMOS transistor is connected to an output end of the third operational amplifier, an inverting input end of the third operational amplifier is connected to a reference voltage, a non-inverting input end of the third operational amplifier is connected to the common end of the second third resistor and the third third resistor, and a drain of the PMOS transistor is connected to an end of the first third resistor away from the second third resistor.

10. An electronic device, comprising: a continuous-time bandpass Sigma-Delta modulator, wherein the continuous-time bandpass Sigma-Delta modulator includes:
a transconductance operational amplifier configured to receive an input voltage signal and convert the input voltage signal to obtain and output a current signal;
a passive resonator connected to an output end of the transconductance operational amplifier as a loop filter and configured to convert the current signal to obtain and output an intermediate voltage signal;
a sampling quantizer connected to an output end of the passive resonator and configured to sample and quantize the intermediate voltage signal to obtain and output a thermometer code;
a current feedback module having an input end connected to an output end of the sampling quantizer and an output end connected to the passive resonator and configured to provide a feedback current for the passive resonator under control of the thermometer code; and
a voltage feedback module having an input end connected to the output end of the sampling quantizer and an output end connected to the passive resonator and configured to provide a feedback voltage for the passive resonator under the control of the thermometer code.

11. The electronic device according to claim 10, wherein the passive resonator includes a capacitor and an inductor; a first end of the capacitor is connected to the output end of the transconductance operational amplifier, a second end of the capacitor is grounded; a first end of the inductor is connected to the output end of the transconductance operational amplifier, a second end of the inductor is connected to the output end of the sampling quantizer through the voltage feedback module connected in series; and the first end of the inductor connected to the output end of the transconductance operational amplifier outputs the intermediate voltage signal.

12. The electronic device according to claim 11, wherein the thermometer code includes a 4-bit thermometer code; the current feedback module includes a first current source, a second current source, a third current source, a fourth current source, a fifth current source, a first switch, a second switch, a third switch, and a fourth switch; an operation voltage is grounded through the first current source, the first switch, and the second current source connected in series in sequence; the operation voltage is also grounded through the first current source, the second switch, and the third current source connected in series in sequence; the operation voltage is also grounded through the first current source, the third switch, and the fourth current source connected in series in sequence; the operation voltage is also grounded through the first current source, the fourth switch, and the fifth current source connected in series in sequence; a control end of the first switch is connected to a first bit of the 4-bit thermometer code; a control end of the second switch is connected to a second bit of the 4-bit thermometer code; a control end of the third switch is connected to a third bit of the 4-bit thermometer code; a control end of the fourth switch is connected to a fourth bit of the 4-bit thermometer code; a common end of the first switch, the second switch, the third switch, and the fourth switch outputs the feedback current; and the feedback current is connected to the output end of the transconductance operational amplifier.

13. The electronic device according to claim 12, wherein the voltage feedback module includes an output voltage adjusting unit, a voltage dividing unit, and a selection output unit; the output voltage adjusting unit outputs an adjustable initial voltage; an input end of the voltage dividing unit is connected to an output end of the output voltage adjusting unit; the voltage dividing unit performs voltage dividing processing in combination with ground, the operation voltage, and the initial voltage to obtain and output a plurality of initial feedback voltages of different values; input ends of the selection output unit are connected to the plurality of initial feedback voltages in a one-to-one correspondence; a control end of the selection output unit is connected to the thermometer code; under the control of the thermometer code, the selection output unit selects one of the plurality of initial feedback voltages as the feedback voltage and outputs the feedback voltage; and an output end of the selection output unit is connected to the second end of the inductor away from the transconductance operational amplifier.

14. The electronic device according to claim 13, wherein the output voltage adjusting unit includes N reference current sources, N digitally controlled switches, a first resistor, a first operational amplifier, and an NMOS transistor; the N reference current sources and the N digitally controlled switches form N parallel current branches; each of the current branches includes one reference current source and one digitally controlled switch connected in series in sequence; an end of each reference current source away from the digitally controlled switch is connected to the operation voltage; control ends of the N digitally controlled switches are connected to N bits of an N-bit digital code in a one-to-one correspondence; ends of the N digitally controlled switches away from the reference current sources are connected to a first end of the first resistor, a second end of the first resistor is grounded; a non-inverting input end of the first operational amplifier is connected to a common end of the N digitally controlled switches, an inverting input end of the first operational amplifier is connected to a source of the NMOS transistor, an output end of the first operational amplifier is connected to a gate of the NMOS transistor, and the source of the NMOS transistor outputs the initial voltage, wherein N is an integer greater than or equal to 2.

15. The electronic device according to claim 14, wherein the voltage dividing unit includes a second resistor and four third resistors; the operation voltage is connected to a drain of the NMOS transistor through a first third resistor, a second third resistor, a third third resistor, and a fourth third resistor connected in series in sequence; the source of the NMOS transistor is grounded through the second resistor connected in series; an end of the first third resistor close to the operation voltage outputs a first initial feedback voltage, the first third resistor and the second third resistor have a common end that outputs a second initial feedback voltage, the second third resistor and the third third resistor have a common end that outputs a third initial feedback voltage, the third third resistor and the fourth third resistor have a common end that outputs a fourth initial feedback voltage, and an end of the fourth third resistor close to the NMOS transistor outputs a fifth initial feedback voltage.

16. The electronic device according to claim 15, wherein the selection output unit includes a data selector and a second operational amplifier; five input ends of the data selector are connected to five initial feedback voltages in a one-to-one correspondence, a control end of the data selector is connected to the thermometer code, an output end of the data selector is connected to a non-inverting input end of the second operational amplifier, an inverting input end of the second operational amplifier is connected to an output end of the second operational amplifier, and the output end of the second operational amplifier outputs the feedback voltage.

17. The electronic device according to claim 15, wherein the voltage feedback module further includes an output common-mode adjustment unit, an output end of the output common-mode adjustment unit is connected to the voltage dividing unit, and the output common-mode adjustment unit is configured to stabilize and clamp a common-mode value of the feedback voltage.

18. The electronic device according to claim 17, wherein the output common-mode adjustment unit includes a third operational amplifier and a PMOS transistor, a source of the PMOS transistor is connected to the operation voltage, a gate of the PMOS transistor is connected to an output end of the third operational amplifier, an inverting input end of the third operational amplifier is connected to a reference voltage, a non-inverting input end of the third operational amplifier is connected to the common end of the second third resistor and the third third resistor, and a drain of the PMOS transistor is connected to an end of the first third resistor away from the second third resistor.
